(19) United States
(12) Patent Application Publication
(10) Pub. No.: US 2026/0282760 A1
(43) Pub. Date: Sep. 17, 2026

(54) METHOD FOR MANUFACTURING GaAs HALL SENSOR

(71) Applicant: TDK-Micronas GmbH, Freiburg (DE)

(72) Inventors: Martin CORNILS, Freiburg (DE); Laurent OSBERGER, Strasbourg (FR); Maria-Cristina VECCHI, Freiburg (DE); Anja FLECK, Herbolzheim (DE); Dag BEHAMMER, Ulm (DE); Armin LANG, Ulm (DE)

(73) Assignee: TDK-Micronas GmbH, Freiburg (DE)

(21) Appl. No.: 19/080,807

(22) Filed: Mar. 15, 2025

(51) Int. Cl. H10N 52/01; G01R 33/00; G01R 33/07; H10N 52/00

(52) U.S. Cl. CPC H10N 52/01; G01R 33/0052; G01R 33/077; H10N 52/101

(57) ABSTRACT

A method for manufacturing a Hall sensor comprising GaAs with a GaAs semiconductor wafer, wherein a process step, a III-V insulation layer is produced on the substrate and, via an epitaxy process, a semiconductor layer comprising GaAs is grown on the insulation layer with an n-doping. A shielding layer comprising n-doped GaAs and bonded to the semiconductor layer is formed, wherein the doping of the shielding layer is higher than the doping of the semiconductor layer. A plurality of masked first regions are generated via a masking process, wherein at least some of the first regions are completely enclosed by strip-shaped mask-free second regions. A vertical insulation layer is created in the second regions with one or more subsequent process steps. Contacts are formed in at least some of the first regions in order to operate the semiconductor layer in the first region as a Hall sensor.

### BACKGROUND OF THE INVENTION

### Field of the Invention

A vertical III-V Hall sensor is known from DE 10 2023 002 342 A1. Here, the vertical III-V Hall sensor has on a GaAs substrate, an insulation layer and a GaAs semiconductor layer arranged on the insulation layer and a second insulation layer formed on the semiconductor layer interrupted by electrical contact regions. The second insulation layer is made of an InGaP compound, among other things. Furthermore, the vertical III-V Hall sensor has circumferential insulation, wherein the circumferential insulation is carried out with hydrogen implantation, among other things.

### Description of the Background Art

Furthermore, different III-V Hall sensors for the measurement of the three components of a magnetic field are known from CN 102 520 376 A. For the measurement of magnetic fields running parallel to a substrate surface, a columnar Hall sensor structure arranged vertically on the substrate surface is disclosed. Here, the columnar structure is contacted at the two front sides, among other things.

Other generic III-V Hall sensors are known from EP 0 204 135 A1, CN 102 244 234 B, DE 10 2011 002580 A1 and CN 105 261 698 A.

### SUMMARY OF THE INVENTION

Against this background, the object of the invention is to specify a method which advances the state of the art.

The object is achieved by a method for manufacturing a Hall sensor comprising GaAs having the features of claim 1. Advantageous embodiments of the invention are the subject of subclaims.

According to the subject-matter of the invention, a method for manufacturing a GaAs Hall sensor is provided.

To carry out the method, a semiconductor wafer made of GaAs formed as a substrate is provided with a top and a bottom and a first lattice constant and a first bandgap. In further development, the semiconductor wafer has a diameter of 100 mm or a diameter of 150 mm or 200 mm and larger. In this case, the semiconductor wafer has a thickness of at least 100 μm when an epitaxy process is performed.

In a process step, a III-V insulation layer comprising the first lattice constant is produced on the top of the GaAs substrate using an epitaxy process.

In another process step, a GaAs semiconductor layer comprising the first lattice constant and an n-doping is grown on the insulation layer using the epitaxy process.

In a further process step, a shielding layer comprising n n-doped GaAs and bonded to the semiconductor layer is epitaxially formed.

The doping of the shielding layer is higher than the doping of the semiconductor layer. Furthermore, the shielding layer is at least 10 times thicker than the semiconductor layer.

In one process step, a plurality of masked first regions are created by means of a masking process. In other words, a mask is formed in the first regions.

At least some of the first regions are completely enclosed by strip-shaped mask-free second regions. It should be noted that in a further development, all the first regions are enclosed by second regions.

In one or more subsequent process steps, a vertical insulation layer is created in the second regions.

In a further process step, contacts are formed in at least some of the first regions in order to operate the semiconductor layer in the first region as a Hall sensor.

After the formation of the contacts in one region, the semiconductor layer has a flat top, wherein the region comprises at least two adjacent first regions electrically insulated from each other by the second region.

It should be noted that the aforementioned process steps are carried out in the order indicated.

It should be noted that the terms ‘contacts, metallic contacts, terminal contacts, and metal contacts’ are used synonymously below.

One advantage of the method is that the formation of a shielding layer surprisingly improves the electrical properties of the Hall sensors formed in the first regions. Since the shielding layer is very thin as compared to the semiconductor layer, an operating current imprinted by the contacts flows almost completely or exclusively through the semiconductor layer.

Another advantage is that the formation of a planar surface allows for the Hall sensors to be electrically contacted in a simple and reliable way even after insulation.

In a further development, the formation of the epitaxially growing layers is carried out by means of a MOVPE process or by means of an LPE process or by means of an MBE process.

It should be noted that the MOVPE method using metal-organic precursors is currently predominantly used in the epitaxial production of GaAs layers.

It should be noted that, in contrast to silicon technology, doping of the GaAs layers is already immanent in the production of the layers.

The implantation of dopants with subsequent activation by temperature steps such as RTA or furnace processes can only be carried out to a limited extent in GaAs, among other things due to the decomposition temperature from approx. 700° C. Furthermore, passivation of GaAs by oxidation of the semiconductor material is also not so easy as compared to using silicon technology. In summary, it should be noted that the manufacture of components in the field of GaAs is not directly compatible with the manufacture of components in the field of silicon technology.

In another further development, the semiconductor layer is grown with a doping in a range between 1·10¹⁴ 1/cm³ and 5·10¹⁷ 1/cm³ or in a range between 5·10¹⁴ 1/cm³ and 1·10¹⁶ 1/cm³ or in a range between 1·10¹⁵ 1/cm³ and 5·10¹⁵ 1/cm³.

It is understood that in order to achieve the highest possible mobility, the doping of the III-V semiconductor layer should be in a range below 1·10¹⁶ 1/cm³ at least for a large part of the thickness. In another further development, the doping of the semiconductor layer is grown with a homogeneous doping. In one embodiment, the semiconductor layer is grown with a doping of 2·10¹⁵ 1/cm³.

In one embodiment, the semiconductor layer is formed with a thickness in a range between 0.5 μm and 15 μm, or with a thickness in a range between 1.0 μm and 8 μm, or with a thickness in a range between 2.0 μm and 5 μm.

In further development, the semiconductor layer consists of GaAs. In another further development, the shielding layer and/or the insulation layer consists of GaAs.

In a further development, the shielding layer is formed with the first lattice constant and the bandgap of the semiconductor layer or substrate.

In one embodiment, the shielding layer is grown with a doping at least a factor of 10 higher than the semiconductor layer, or with a doping in a range between 5·10¹⁶ 1/cm³ and 1·10¹⁸ 1/cm³, or with a doping in a range between 1·10¹⁷ 1/cm³ and 5·10¹⁷ 1/cm³.

In another embodiment, the shielding layer is grown with a thickness in a range between 20 nm and 200 nm, or with a thickness in a range between 50 nm and 100 nm, or with a thickness in a range between 65 nm and 75 nm.

In another further development, a III-V cover layer with the first lattice constant is epitaxially grown in a process step on a semiconductor layer that is materially bonded to the shielding layer, wherein the cover layer is formed from a different material with a higher bandgap than the semiconductor layer.

In one embodiment, the cover layer is formed with a thickness in a range between 3 nm and 50 nm or with a thickness in a range between 5 nm and 15 nm.

In another embodiment, the cover layer is produced with an n-doping in a range between 5·10¹⁷ 1/cm³ and 5·10¹⁹ 1/cm³ or in a range between 1·10¹⁸ 1/cm³ and 1·10¹⁹ 1/cm³.

In a further development, the cover layer is formed with a compound comprising or consisting of InGaP. In a further development, the thickness of the cover layer in the regions between the metal contacts is lower than in comparison to the regions below the metal contacts.

In another further development, the cover layer has a bottom formed on the shielding layer and a top opposite the bottom, wherein a delta doping is formed on the bottom and/or on the top for a reduction of contact barriers.

One advantage of delta doping is that the conductivity at the contact layer is metallic, i.e., very low-impedance. In other words, the Fermi level is in the conduction band.

In another further development, delta doping is carried out with Si during the growth of the layers during epitaxy. For example, in a MOVPE system for the formation of an Si delta doping, a corresponding precursor is switched on and off again for a short time.

In another further development, when masking the first regions, a mask made of one material, or a mask made of several layers of different materials is used.

In one embodiment, a mask comprising an organic photoresist is formed on the surface of the semiconductor wafer, i.e., on the surface of the last epitaxially applied semiconductor layer.

In another embodiment, a SiN layer is first deposited before the organic paint is applied, preferably by means of a PECVD or PVD process, in order to protect the surface from contamination. In a subsequent process step, the photoresist is then formed over the entire surface and either immediately structured or coated with a metal layer before structuring and then structured.

It should be noted that with the structuring in the second regions, the mask is removed in order to then form the vertical insulation layer.

In a further development, the vertical insulation layer in the second regions is formed up to the insulation layer above the GaAs substrate or into the insulation layer. In other words, the vertical insulation layer is formed as a circumferential full-surface vertical layer from the semiconductor surface up to the first insulation layer. In connection with the insulation layer, the enclosed neighboring first regions are completely electrically insulated from each other. It is understood that the first regions are also insulated from the substrate by means of the insulation layer.

In a further development, the second regions have a width between 1.0 μm and 50 μm or a width between 2 μm and 5 μm.

In another further development, the vertical insulation layer is formed from the top of the semiconductor layer beyond the insulation layer, i.e., into the substrate. This creates particularly reliable electrical insulation between neighboring first regions.

In one embodiment, the vertical insulation layer is created by means of hydrogen implantation, and after implantation on the first regions, the mask is removed, or the vertical insulation layer is created by a trench process. In each case, after the formation of the vertical insulation layer in a region comprising at least several of the first regions and at least one or more of the second regions, there is a planar surface.

In another embodiment, a p/n junction is created to form the first insulation layer and/or the insulation layer is formed from a III-V material with a second bandgap, wherein the second bandgap is larger than the first bandgap.

In a further development, a GaAs p-doped sublayer and a GaAs n-doped sublayer are formed as an insulation layer, wherein the p-doped sublayer is bonded to the substrate and the n-doped sublayer is bonded to the semiconductor layer.

In another further development, the two sublayers are grown lattice-matched to the lattice constant of the substrate by means of the epitaxy process, wherein the n-doped sublayer has a higher doping than the semiconductor layer. In another further development, the p-doped sublayer is formed with a doping in a range between 1·10¹⁴ 1/cm³ and 1·10¹⁶ 1/cm³ or with a doping in a range between 1·10¹⁵ 1/cm³ and 8·10¹⁵ 1/cm³ and the n-doped sublayer with a doping in a range between 1·10¹⁵ 1/cm³ and 1·10¹⁷ 1/cm³ or with a doping in a range between 8·10¹⁵ 1/cm³ and 5·10¹⁷ 1/cm³.

In one embodiment, the p-doped sublayer is formed with a thickness in a range between 50 nm and 2.0 μm or with a thickness in a range between 100 nm and 800 nm and the n-doped sublayer with a thickness in a range between 10 nm and 300 nm or with a thickness in a range between 30 nm and 100 nm.

In another embodiment, at least one n-doped III-V contact layer is formed in an epitaxial process step on the cover layer or on the shielding layer, in order to form a low-impedance electrical connection with the cover layer or with the shielding layer after the formation of metallic terminal contacts.

In a further development, the contact layer in the contact-free regions is removed during the formation of the metallic terminal contacts, so that the contact layer is formed exclusively between the cover layer and the terminal contacts.

In another further development, the contact layer is formed with the first lattice constant and/or the contact layer is formed with the same bandgap as the semiconductor layer.

In an embodiment, the contact layer is formed as an n-doped GaAs layer and/or an n-doped InGaAs comprising layer, or the contact layer is formed from an n-doped GaAs layer and/or an n-doped InGaAs layer.

In a further development, the contact layer has a first GaAs sublayer and a second InGaAs sublayer. In this case, the two sub-layers are bonded to each other. The first sublayer is also bonded to the shielding layer or to the cover layer.

The second sub-layer is bonded to the metal contact. It is understood that the two sublayers are formed exclusively below the metal contacts in order to avoid a shunt of the semiconductor layer.

In one embodiment, the contact layer is formed with a total thickness in a range between 10 nm and 150 nm or in a range between 30 nm and 100 nm.

In another embodiment, the doping of the contact layer is formed above 1·10¹⁸ 1/cm³ or above 5·10¹⁸ 1/cm³ or above 1·10¹⁹ 1/cm³.

In a further development, at least a first geometric embodiment and a second geometric embodiment are formed as the first regions, wherein the two embodiments of the first regions are insulated from each other by means of a second region.

In another further development, the first embodiment is formed in a plan view of the semiconductor surface as a rectangular or a square or a cross-shaped or an octagonal surface for the formation of a lateral Hall sensor, and the second embodiment is designed for the formation of a vertical Hall sensor in a rectangular or in a double-axe-shaped or in a butterfly-shaped design.

In a further development, exactly four or exactly eight terminal contacts are formed in the first embodiment and exactly three terminal contacts or exactly four or exactly five or exactly six or exactly seven terminal contacts are formed in the second embodiment.

In another further development, several first regions of the second embodiment are directly adjacent to each other, with the first regions each insulated from each other by means of a second region.

In one embodiment, a region with the second embodiment is formed on two sides of the first embodiment, wherein the two regions of the second embodiment are arranged orthogonally to each other to form a 3D Hall sensor in the form of a pixel cell.

Here, the first embodiment detects a Z component of a magnetic field, and the first two regions of the second embodiment detect an X component and a Y component of the magnetic field.

It should be noted that a magnetic field component formed orthogonally on the semiconductor surface is called a Z component, and two components orthogonal to each other and running along the plane of the semiconductor surface are called X and Y components, respectively.

In a further development, first regions of the second embodiment are formed around a central first region of the first embodiment on at least two sides or circumferentially on all sides in order to form a 3D Hall sensor.

In another further development, at least some of the second regions are formed as guard rings. It is understood that trenches are created by means of a trench process, for example, and that after the formation of a sidewall insulation, the trenches are electrically connected by filling them with a conductive material and forming electrical contacts.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The invention is explained in more detail below with reference to the drawings. Here, similar parts are labeled with identical signs. The embodiments shown are strongly schematized, i.e., the distances and the lateral and vertical extensions are not true-to-scale and, unless otherwise stated, do not have any derivable geometric relations to each other. The drawings show

FIG. 1a-c cross-sectional views of the manufacturing stages of the method for the formation of a first embodiment of a Hall sensor,

FIG. 2 a cross-sectional view of a second embodiment of a Hall sensor,

FIG. 3 a top view of a semiconductor wafer with lateral Hall sensors,

FIG. 4a-c top views of different embodiments of lateral Hall sensors,

FIG. 5a-d top views of different embodiments of vertical Hall sensors,

FIG. 6a-d top views of different embodiments of pixel cells,

FIG. 7 a cross-sectional view of a pixel cell of an embodiment of FIG. 6d.

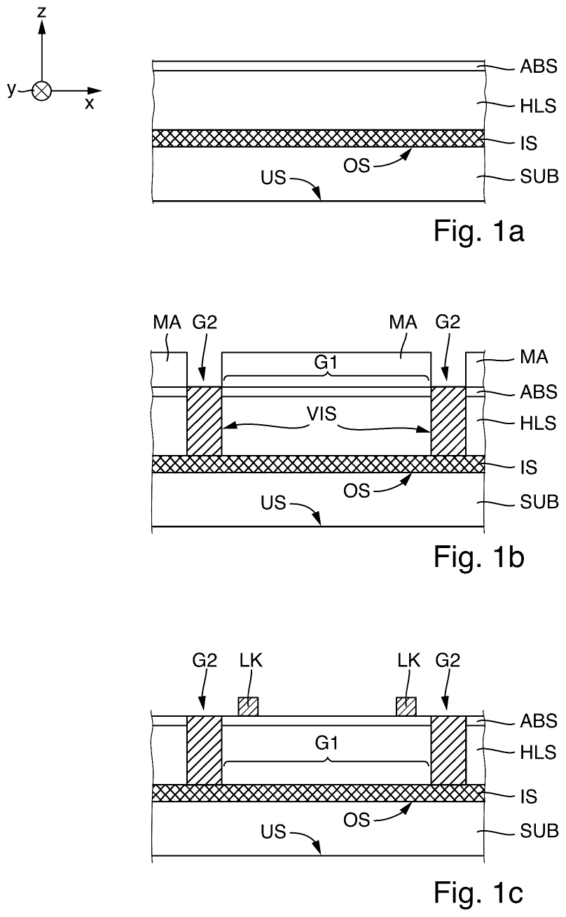

The illustrations of FIGS. 1a-c show cross-sectional views of the manufacturing stages of the method for the formation of a first embodiment of a GaAs Hall sensor. For reasons of clarity, a Cartesian coordinate system is drawn. According to this, the cross-sections are formed in an X-Z plane.

### DETAILED DESCRIPTION

According to FIG. 1a, a III-V insulation layer IS is produced on a semiconductor wafer formed as a GaAs substrate SUB by means of an epitaxy process with a top OS and a bottom US in a process step on the top OS of the GaAs substrate SUB.

The substrate SUB has a first lattice constant and a first bandgap. The III-V insulation layer IS is grown on the substrate with the first lattice constant. The substrate is designed as a semi-isolated GaAs semiconductor wafer.

In a further process step, an n-doped GaAs semiconductor layer HLS with the first lattice constant is grown on the insulation layer IS using an epitaxy process.

In a subsequent process step, an n-doped GaAs shielding layer ABS is epitaxially formed on the semiconductor layer HLS, wherein the doping of the shielding layer ABS is greater than the doping of the semiconductor layer HLS.

The shielding layer ABS has the same lattice constant as the semiconductor layer HLS and a layer thickness that is at least 10 times lower than the semiconductor layer HLS.

According to the illustration of FIG. 1b, a plurality of masked first regions G1 and second mask-free regions G2 are generated in a subsequent process step by means of a masking process.

The first regions G1 are completely enclosed by the strip-shaped mask-free second regions G2.

In subsequent process steps, a vertical insulation layer VIS is created in the second regions.

In a process step not shown, the mask is removed in the first regions G1. In other words, in a non-depicted top view, the top of the semiconductor wafer is free of paint and flat.

According to the illustration of FIG. 1c, in a subsequent process step, several metal contacts LK are formed on the first region G1 in order to form the semiconductor layer HLS in the first region G1 as a Hall sensor.

The semiconductor wafer is designed to be flat at the top of the shielding layer ABS according to the formation of the contacts LK. In other words, a region comprising first regions G1, which are formed as Hall sensor regions, and second regions G2, which are formed as vertical isolation regions, have no steps at the top of the shielding layer ABS.

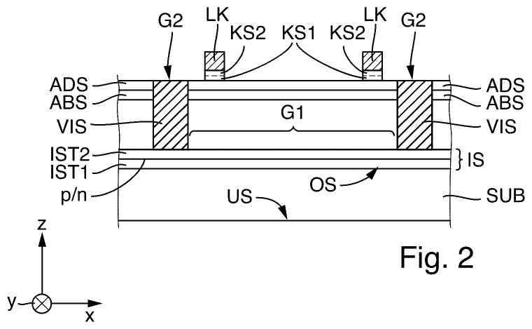

FIG. 2 shows a cross-sectional view of a second embodiment of a Hall sensor. In the following, only the differences to the first embodiment, shown in connection with the illustration of FIG. 1c, are explained.

On the top of the shielding layer ABS, a thin InGaP cover layer ADS is formed, wherein the cover layer ADS has a first lattice constant. The vertical insulation layer VIS also penetrates the InGaP cover layer ABS.

Below the contacts LK, a first contact layer KS1 consisting of n-doped GaAs is formed on the top of the cover layer ADS. The first contact layer KS1 has a doping of more than 1·10¹⁷ 1/cm³. Between the first contact layer KS1 and the bottom of the contacts LK, a second n-doped contact layer KS2 with the first lattice constant is formed. Preferably, the second contact layer KS2 has a doping above 5·10¹⁸ 1/cm³ and is formed of InGaAs.

The insulation layer IS has a p-doped GaAs sublayer IST1 and an n-doped GaAs sublayer IST2. As a result, the two sublayers form a p/n transition, and the semiconductor layer HLS is electrically insulated from the substrate.

The p-doped sublayer IST1 is formed between the substrate SUB and the n-doped sublayer IST2. The n-doped sublayer IST2 is formed between the p-doped sublayer IST1 and the semiconductor layer HLS.

In a non-shown embodiment, the vertical insulation layer VIS penetrates the two sublayers IST1 and IST2 and extends into the substrate SUB.

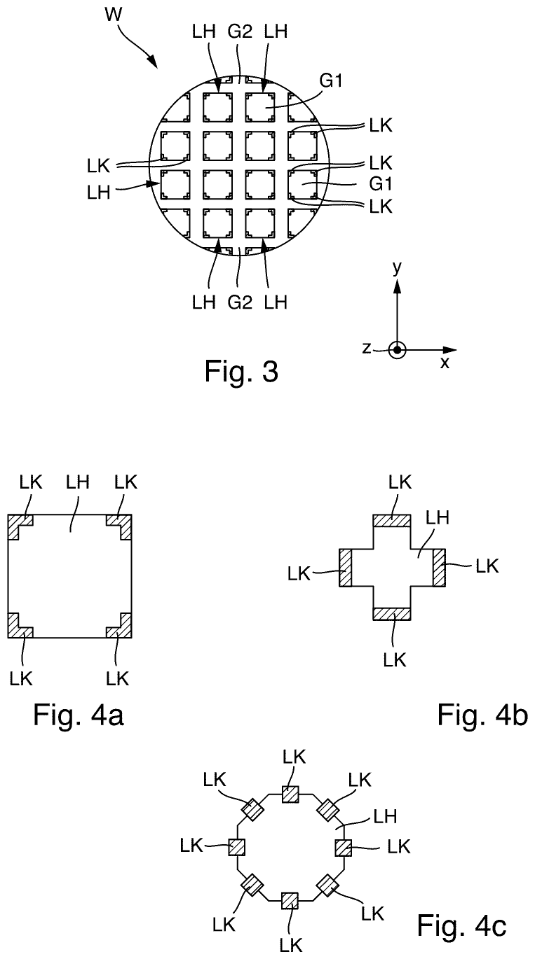

FIG. 3 shows a top view of a semiconductor wafer formed in the X-Y plane with a plurality of Hall sensors. In the following, only the differences to the embodiments, shown in connection with the illustration of FIG. 1c or FIG. 2, are explained.

The Hall sensors formed in the first regions G1 are designed as lateral Hall sensors LH, in the form of so-called Hall plates. The individual lateral Hall sensors LH have a square geometry. Metal contacts LK are formed at the respective edges in the corners.

Each of the lateral Hall sensors LH is completely enclosed by a second region G2.

For reasons of clarity, conductor paths for connecting the metal contacts are not marked.

FIGS. 4a-c show top views of different embodiments of individual lateral Hall sensors LH formed in the X-Y plane. In the following, only the differences to the embodiments, shown in connection with the illustration of FIG. 3, are explained.

FIG. 4a shows a detailed representation of the square embodiment of the lateral Hall sensor LH of FIG. 3. For reasons of clarity, a representation of the second regions is not shown.

The four metal contacts LK are symmetrically designed at the four corners of the Hall plate. It is understood that the Hall plate can be used to detect a magnetic field component formed in the Z direction.

FIG. 4b shows a cross-shaped formation of a lateral Hall sensor LH. The respective metal contacts LK are formed at the cross-shaped ends. It is understood that the individual branches of the cross-shaped design are symmetrical to each other.

FIG. 4c shows an octagonal formation of a lateral Hall sensor LH. The respective metal contacts LK are formed at the octagonal ends. It is understood that the individual branches of the octagonal version are symmetrical to each other.

In an embodiment not shown here, FIGS. 4a and 4 b are rotated by 45° in the x-y plane around the z-axis.

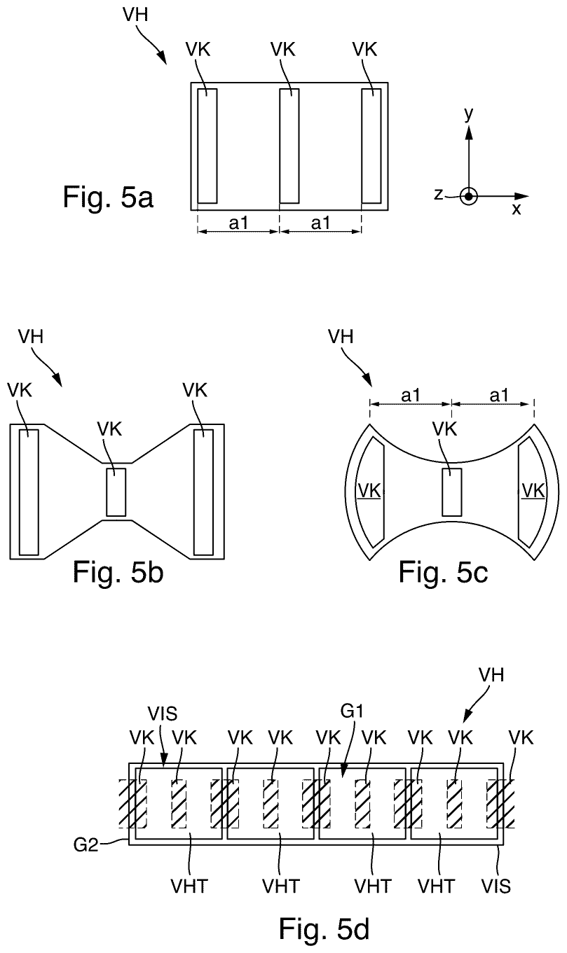

FIG. 5a-d shows top views of different embodiments of individual vertical Hall sensors VH formed in the X-Y plane. In the embodiments shown, the vertical Hall sensors VH can be used to detect a magnetic field formed in the Y direction. In the following, only the differences to the previous embodiments are explained.

FIG. 5a shows a top view of a rectangular embodiment of a vertical Hall sensor VH. For reasons of clarity, a representation of the second regions is not shown.

The vertical Hall sensor VH has three metal contacts VK of equal length in the Y-direction. The middle metal contact VK is spaced from the two outer metal contacts VK in the X direction by a distance a1.

In an embodiment not shown, the two outer contacts VK are formed to the edge of the first region G1 or beyond.

FIG. 5b shows another double-axe-shaped embodiment of a vertical Hall sensor VH. In the following, only the differences to the embodiment shown in FIG. 5a are explained.

The two outer metal contacts VK are the same width in the Y-direction and much wider than the middle metal contact VK. All three metal contacts VK have a rectangular extension in the top view shown.

The first region G1 shows a mirror symmetry with respect to a mirror axis running in the Y-direction through a center of the middle metal contact VK.

FIG. 5c shows a butterfly-shaped extension with two wings, with a mirror axis formed in the Y direction running through the middle of the middle metal contact VK.

The two wings are each crescent-shaped. In other words, the outer edge of region G1 has no straight lines but instead is formed by arc-shaped segments.

In contrast to the middle metal contact VK, the two outer metal contacts VK are not rectangular, but are designed as circular segments.

FIG. 5d shows another embodiment of a vertical Hall sensor VH. In the following, only the differences to the embodiment shown in FIG. 5a are explained.

There are four first regions G1 lined up in the X direction, wherein a vertical partial Hall sensor VHT with three metal contacts VK is formed in each of the first regions G1. The first four regions are separated from each other by second regions G2 and are also completely enclosed by the second regions G2.

By connecting the outer metal contacts VK of adjacent vertical Hall sensors, the entire structure forms a vertical Hall sensor VH, consisting of four partial Hall sensors VHT, with four middle metal contacts VK.

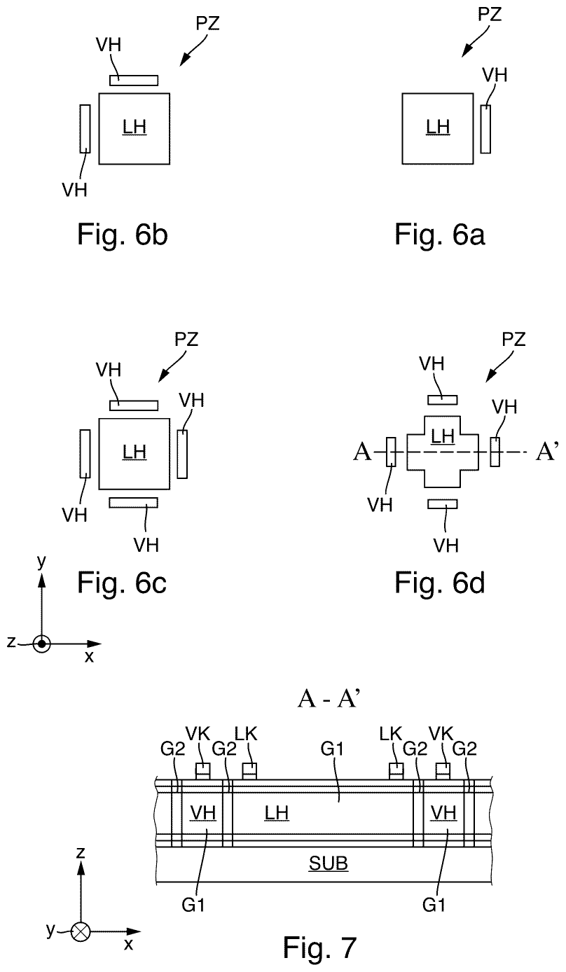

FIG. 6a-d shows top views of different embodiments of pixel cells PZ. It is understood that the term pixel cell refers to an extremely compact arrangement of Hall sensors with which different components, at least two, of a magnetic field can be detected at almost the same location. In the following, only differences to the previous embodiments are explained.

FIG. 6a shows a 2D pixel cell PZ, having a lateral Hall sensor LH in a square formation with a vertical Hall sensor VH on one side of the square.

It is understood that the two Hall sensors LH and VH are each arranged in a first region. With the embodiment shown, the Z component and the X component of a magnetic field can be detected.

FIG. 6b shows a 3D pixel cell PZ, having a lateral Hall sensor LH in a square formation with vertical Hall sensors VH arranged on two adjacent sides of the square. With the embodiment shown, the Z component and the X and Y components of a magnetic field can be detected.

FIG. 6c shows a 3D pixel cell PZ, having a lateral Hall sensor LH in a square formation in the middle with vertical Hall sensors VH arranged on all sides of the square.

FIG. 6d shows a 3D pixel cell PZ, having a lateral Hall sensor LH in a cross-shaped formation in the middle with vertical Hall sensors VH arranged on all side branches. A cutting line A-A′ is drawn.

FIG. 7 shows a cross-sectional view along the cutting line A-A′ of the 3D pixel cell PZ of the embodiment of FIG. 6d, wherein reference is made to the structure shown in FIG. 2.

It can be seen that in the first regions g1 either a vertical hall sensor VH or a lateral hall sensor LH is formed.

The LH lateral hall sensor is surrounded at both ends by the vertical hall sensors VH.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

1. Method for manufacturing a Hall sensor comprising GaAs, with
a semiconductor wafer made of GaAs formed as a substrate with a top and a bottom and a first lattice constant and a first bandgap,
a process step on the top of the GaAs substrate, in which a III-V insulation layer with the first lattice constant is produced by means of an epitaxy process,
a process step on the insulation layer, in which a GaAs semiconductor layer with the first lattice constant and an n-doping is grown using an epitaxy process,
a process step, in which a shielding layer comprising n-doped GaAs is formed epitaxially with the semiconductor layer, wherein the doping of the shielding layer is higher than the doping of the semiconductor layer and the shielding layer has a thickness at least 10 times lower than the semiconductor layer,
a process step, in which a plurality of masked first regions are created by means of a masking process, wherein at least some of the first regions are completely enclosed by strip-shaped mask-free second regions, wherein a vertical insulation layer is created in the second regions with one or more subsequent process steps,
a process step in which contacts are formed in at least some of the first regions in order to operate the semiconductor layer in the first regions as a Hall sensor,
a flat top of the semiconductor layer after the formation of the contacts, in a region comprising at least two adjacent first regions electrically insulated from each other by second regions,
the condition that the aforementioned process steps are executed in the specified order.

2. Method according to claim 1, characterized in that the semiconductor layer and/or the shielding layer and/or the insulation layer is composed of GaAs.

3. Method according to claim 1, characterized in that in one process step a III-V cover layer is epitaxially grown on the shielding layer with the first lattice constant, wherein the cover layer is formed of a different material with a higher bandgap than the shielding layer.

4. Method according to claim 3, characterized in that the cover layer has a bottom formed on the shielding layer and a top opposite the bottom and a delta doping is formed on the bottom and/or on the top for a reduction of contact barriers.

5. Method according to claim 1, characterized in that the shielding layer is formed with the first lattice constant and the bandgap of the semiconductor layer.

6. Method according to claim 1, characterized in that the vertical insulation layer is formed in the second regions up to the insulation layer.

7. Method according to claim 1, characterized in that the vertical insulation layer is created by means of hydrogen implantation and after implantation the mask is removed on the first regions, or the vertical insulation layer is created by a trench process, wherein after the formation of the vertical insulation layer, there is a planar surface in a region comprising at least several of the first regions and at least one or more of the second regions.

8. Method according to claim 1, characterized in that a p/n transition is generated for the formation of the insulation layer and/or the insulation layer is formed from a III-V material with a second bandgap, wherein the second bandgap is greater than the first bandgap.

9. Method according to claim 8, characterized in that the two sublayers are grown lattice-matched to the lattice constant of the substrate by means of the epitaxy process, wherein the n-doped sublayer has a higher doping than the semiconductor layer.

10. Method according to claim 1, characterized in that in an epitaxial process step at least one n-doped III-V contact layer is formed on the cover layer or on the shielding layer in order to form a low-impedance electrical connection with the cover layer or with the shielding layer after the formation of metallic terminal contacts.

11. Method according to claim 10, characterized in that during the formation of the metallic terminal contacts, the contact layer is removed in the contact-free regions, so that the contact layer is formed exclusively between the cover layer and the terminal contacts.

12. Method according to claim 1, characterized in that at least a first geometric embodiment and a second geometric embodiment are formed as the first regions and that the first regions are isolated from each other by means of a second region.

13. Method according to claim 12, characterized in that the first embodiment in a plan view of the semiconductor surface is formed as a square or a rectangular or a cross-shaped or an octagonal surface for the formation of a lateral Hall sensor, and the second embodiment for the formation of a vertical Hall sensor is formed in a rectangular or in a double axe-shaped or in a butterfly-shaped design.

14. Method according to claim 12, characterized in that exactly four or exactly eight terminal contacts are formed in the first embodiment and exactly three terminal contacts or exactly four or exactly five or exactly six or exactly seven terminal contacts are formed in the second embodiment.

15. Method according to claim 12, characterized in that several first regions of the second embodiment are directly adjacent to each other, wherein the first regions are isolated from each other by means of a second region.

16. Method according to claim 12, characterized in that on two sides of the first embodiment in each case a region with the second embodiment is formed, wherein the two regions of the second embodiment are arranged orthogonally to each other to form a 3D Hall sensor in the form of a pixel cell, in order to detect a Z-component of a magnetic field with the first region of the first embodiment and with the two first regions of the second embodiment, an X component and a Y component of the magnetic field.

17. Method according to claim 12, characterized in that around a central first region of the first embodiment on the sides, first regions of the second embodiment are formed circumferentially in order to form a 3D Hall sensor.

18. Method according to claim 1, characterized in that at least some of the second regions are formed as guard rings.
